(19) United States
(12) Patent Application Publication
(10) Pub. No.: US 2007/0275514 A1
(43) Pub. Date: Nov. 29, 2007

(54) Semiconductor device and method of manufacturing same

(75) Inventor: Masayuki Itou, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/802,757

(22) Filed: May 24, 2007

(30) Foreign Application Priority Data
May 26, 2006 (JP) 2006-147098

(51) Int. Cl. H01L 21/84; H01L 21/00; H01L 21/76

(52) U.S. Cl. 438/151; 438/149; 438/164; 438/430; 438/424

(57) ABSTRACT

Semiconductor device is prevented from undergoing decline in characteristics and reliability even if width of isolation trench is reduced. Semiconductor device includes: substrate obtained by building up second silicon substrate on first silicon substrate via silicon oxide film; element-forming region in which elements (gate electrode and source/drain region) have been formed; substrate-contact aperture region in which substrate-contact aperture has been formed; isolation trench region in which an isolation trench isolating elements on the second silicon substrate has been formed; polysilicon filling the isolation trench; a prepared hole penetrating silicon oxide films of the substrate-contact aperture region and leading to the first silicon substrate; and a wiring layer connected to the first silicon substrate within the prepared hole.

### FIELD OF THE INVENTION

This invention relates to a semiconductor device that employs a substrate having an SOI structure and to a method of manufacturing this semiconductor device. More particularly, the invention relates to a semiconductor device having an isolation trench.

### BACKGROUND OF THE INVENTION

A semiconductor device using a substrate having an SOI (Silicon On Insulator) structure is formed by a technique such as the SIMOX (Separation by Implanted Oxygen) method employing implantation of oxygen ions or a silicon-substrate bonding method. By way of example, as indicated by the semiconductor device illustrated in FIG. 11, the semiconductor device has a laminate structure that includes a first silicon substrate 101 serving as a supporting substrate, a silicon oxide film 103 built up on the first silicon substrate and serving as an insulator, and a second silicon substrate 102 built up on the silicon oxide film and serving as a surface substrate. With a semiconductor device that uses a substrate having such as SOI structure, it is possible to achieve a high withstand (breakdown) voltage and a high degree of integration by employing an isolation trench in element isolation.

A conventional method of manufacturing a semiconductor device that uses a substrate having an SOI structure will be described with reference to FIG. 11. FIG. 11 is a partial sectional view schematically illustrating the structure of a semiconductor device described in Patent Document 1 (an example of the related art).

According to this method of manufacture, an isolation trench 109 for isolating an element-forming region 150 is formed. At the same time, a substrate-contact region 110 set in an appropriate vacant region also is formed. When the isolation trench 109 is filled completely with a TEOS oxide film 111, the TEOS oxide film 111 is built up on the bottom of the substrate-contact region 110 to a film thickness equivalent to the flat portion of the element-forming region 150. Apertures for contacts 115s, 115g, 115d of the element-forming region 150 and for a substrate contact 115c are then formed individually (or simultaneously). This is followed by forming wiring 116. As a result, it is possible to connect the supporting substrate (first silicon substrate 101) to an electrode 200G for external connection of the substrate surface without enlarging and complicating the manufacturing process for forming the substrate contact 115c.

[Patent Document 1]

JP Patent No. 3510576

### SUMMARY OF THE DISCLOSURE

According to the present invention, the following analyses are given on the related art. The entire disclosure or the aforementioned Patent Document is incorporated herein by reference thereto.

As a result of increasingly higher integration of semiconductor devices, the proportion of the surface area of the semiconductor device occupied by isolation trenches has increased. This has made it necessary to reduce the width of isolation trenches and thereby enlarge the regions in which elements can be formed.

With the example of the related art described in Patent Document 1, however, the TEOS oxide film 111 is used as the material for filling the isolation trench 109. Consequently, burying is unsatisfactory when the trench is filled. Further, if the width of the isolation trench 109 is reduced in excess of a certain amount, a void or seam develops in the TEOS oxide film 111 within the isolation trench 109, a sufficient isolation breakdown voltage cannot be assured and there is the danger that the semiconductor device will experience a decline in characteristics and reliability. If a sufficient isolation breakdown voltage cannot be assured, the potential of the supporting substrate (first silicon substrate 101) cannot be fixed, element breakdown voltage fluctuates, the characteristics of the semiconductor device deteriorate and this can lead to malfunction.

Accordingly, it is an object of the present invention to so arrange it that a semiconductor device will not experience degraded characteristics and a decline in reliability even if the width of isolation trenches is reduced.

According to a first aspect of the present invention, there is provided a semiconductor device comprising: a substrate obtained by building up on a first semiconductor substrate a second semiconductor substrate via a first insulating film; an element-forming region in which an element has been formed on the second semiconductor substrate; a substrate contact aperture region in which an aperture has been formed by removing the second semiconductor substrate; an isolation trench region in which an isolation trench has been formed for isolating the element on the second semiconductor substrate; a second insulating film that has been formed on the surface of the isolation trench; and polysilicon filling the isolation trench. The semiconductor device further comprises: a prepared hole (base hole) penetrating the first insulating film of the substrate contact aperture region and leading to the first semiconductor substrate; and a wiring layer connected to the first semiconductor substrate within the prepared hole.

The prepared hole may penetrate also a third insulating film that has been formed on the first insulating film of the substrate contact aperture region.

The prepared hole may have a step (or shoulder).

According to a second aspect of the present invention, there is provided a method of manufacturing a semiconductor device, comprising the steps of: forming a field insulating film in a region other than an element-forming region on a substrate obtained by building up on a first semiconductor substrate a second semiconductor substrate via a first insulating film; forming on the field insulating film a hard mask having a pattern portion for forming an isolation trench and a substrate contact aperture; removing the field insulating film and the second semiconductor substrate that are exposed from the pattern portion of the hark mask, thereby exposing the first insulating film and forming the isolation trench and the substrate contact aperture; forming a second insulating film on the surface of at least the second semiconductor substrate in the isolation trench and substrate contact aperture; and depositing polysilicon to a prescribed thickness so as to completely fill at least the isolation trench. The method further comprises: etching back the polysilicon by a prescribed amount; removing the hard mask after forming an insulating film on the surface of the polysilicon; forming a prepared hole (base hole) that leads to the first semiconductor substrate by removing at least the first insulating film within the substrate contact aperture; and forming a wiring layer on the first semiconductor substrate within the prepared hole.

The method may further comprise the following steps between the step of removing the hard mask and the step of forming the prepared hole: forming a desired element in the element-forming region; and forming an inter-layer insulating film on the entire surface of the substrate; wherein the step of forming the prepared hole includes forming a prepared hole that leads to the first semiconductor substrate by removing the inter-layer insulating film and the first insulating film within the substrate contact aperture and, at the same time, forming a prepared hole that leads to the element by removing the inter-layer insulating film in the element-forming region.

The method may further comprise: a step of forming a contact plug at least in the prepared hole that leads to the element, this step being inserted between the step of forming the prepared hole and the step of forming the wiring layer; wherein the step of forming the wiring layer includes forming the wiring layer on the contact plug as well.

The step of forming the prepared hole includes: forming a first prepared hole by removing films from the inter-layer insulating film to the first insulating film within the substrate contact aperture in such a manner that the first prepared hole has a bottom extending from the inter-layer insulating film to the first insulating film; and subsequently forming a second prepared hole having a width smaller than that of the first prepared hole by removing films from the inter-layer insulating film to the first insulating film within the first prepared hole in such a manner that the second prepared hole leads to the first semiconductor substrate.

In accordance with the present invention, polysilicon exhibiting an excellent burying property is used as the material for filling the isolation trench. This makes it possible to reduce the width of the isolation trench. As a result, the proportion of the surface area of the semiconductor device occupied by the isolation-trench region can be reduced. This leads to higher integration of the semiconductor device.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a partial sectional view schematically illustrating the structure of a semiconductor device according to a first example of the present invention;

FIGS. 2A to 2D are first process sectional views schematically illustrating a method of manufacturing a semiconductor device according to the first example;

FIGS. 3A to 3D are second process sectional views schematically illustrating a method of manufacturing a semiconductor device according to the first example;

FIGS. 4A to 4D are third process sectional views schematically illustrating a method of manufacturing a semiconductor device according to the first example;

FIGS. 5A to 5D are fourth process sectional views schematically illustrating a method of manufacturing a semiconductor device according to the first example;

FIGS. 6A to 6C are fifth process sectional views schematically illustrating a method of manufacturing a semiconductor device according to the first example;

FIG. 7 is a sectional view schematically illustrating a modification of a method of manufacturing a semiconductor device according to the first example;

FIG. 8 is a partial sectional view schematically illustrating the structure of a semiconductor device according to a second example of the present invention;

FIGS. 9A to 9C are first process sectional views schematically illustrating a method of manufacturing a semiconductor device according to the second example;

FIGS. 10A and 10B are second process sectional views schematically illustrating a method of manufacturing a semiconductor device according to the second example; and

FIG. 11 is a partial sectional view schematically illustrating the structure of a semiconductor device according to an example of the related art.

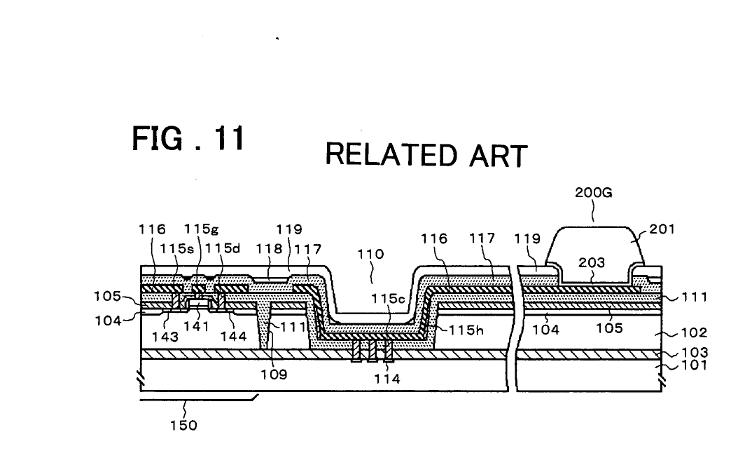

### PREFERRED MODES OF THE INVENTION

### FIRST EXAMPLE

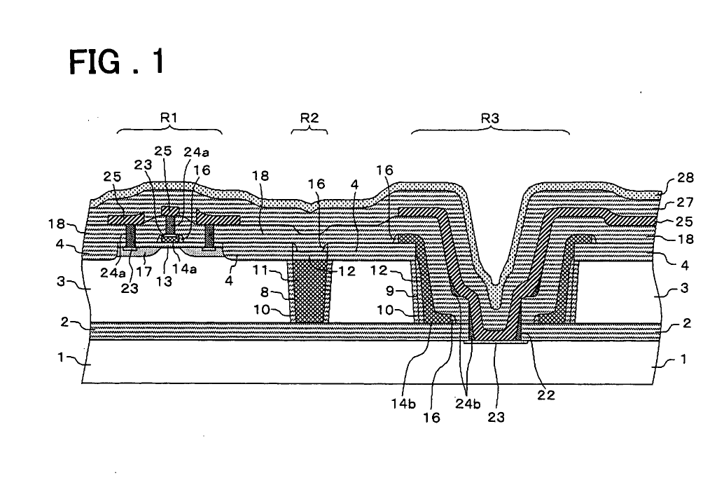

A semiconductor device according to a first example of the present invention will be described with reference to the drawings. FIG. 1 is a partial sectional view schematically illustrating the structure of a semiconductor device according to the first example of the present invention.

This semiconductor device includes an element-forming region R1, an isolation trench region R2 and a substrate-contact aperture region R3 on an SOI (Silicon On Insulator)-based substrate obtained by building up, on a first silicon substrate 1, a silicon oxide film 2 and a second silicon substrate 3 in the order mentioned.

The first silicon substrate 1 is a supporting substrate for which a P-type silicon substrate can be used, by way of example. The silicon oxide film 2 is an insulating film comprising silicon oxide formed on the main surface of the first silicon substrate 1. The second silicon substrate 3 is a surface substrate for which a P-type silicon substrate can be used, by way of example.

The element-forming region R1 is a region in which elements such as MOS transistors have been formed. In the element-forming region R1, a region is surrounded by a silicon oxide film 4 serving as a field insulating film. A gate electrode 14a comprising polysilicon is formed on the second silicon substrate 3, which serves as a channel, via a silicon oxide film 13 serving as a gate insulating film. An impurity diffusion region 17 serving as a source/drain region is formed on both sides of the channel. The gate electrode 14a is electrically connected to a corresponding wiring layer 25 (aluminum, etc.) through a prepared hole, which has been formed in a silicon oxide film 18 serving as an inter-layer insulating film, via a contact region 23, in which an impurity (e.g., boron) for contact is introduced to the gate electrode 14a, and a contact plug 24a comprising tungsten, etc. The impurity diffusion region 17 is electrically connected to a corresponding wiring layer 25 (aluminum, etc.) through a prepared hole, which has been formed in the silicon oxide film 18 serving as an inter-layer insulating film, via a contact region 23, in which an impurity (e.g., boron) for contact is introduced to the impurity diffusion region 17, and a contact plug 24a comprising tungsten, etc. A silicon oxide film 27 and a silicon nitride film 28 serving as cover films are built up on the wiring layer 25 in the order mentioned.

The isolation trench region R2 is a region in which an isolation trench 8 that isolates an element of elements on the second silicon substrate 3 has been formed. The isolation trench region R2 is placed between the element-forming region R1 and the substrate-contact aperture region R3. In the isolation trench region R2, the isolation trench 8 is formed passing through a silicon oxide film 4, which serves as a field insulating film, and the second silicon substrate 3, and has the silicon oxide film 2 as its bottom. A silicon oxide film 10 serving as an insulating film is formed on the side walls of the isolation trench 8. The interior of the isolation trench 8, which is surrounded by a silicon oxide film 10, is filled with polysilicon 11 having an excellent burying property. A silicon oxide film 12 serving as an insulating film, and the silicon oxide film 18, silicon oxide film 27 and silicon nitride film 28 are built up (laminated) on the polysilicon 11 in the order mentioned.

The substrate-contact aperture region R3 is a region in which an aperture has been formed in an appropriate vacant region on the substrate by removing the second silicon substrate 3 in order to make contact with the first silicon substrate 1. In the substrate-contact aperture region R3, a substrate-contact aperture 9 is formed passing through the silicon oxide film 4, which serves as a field insulating film, and the second silicon substrate 3, and has the silicon oxide film 2 as its bottom. In the substrate-contact aperture region R3, the silicon oxide film 10 serving as an insulating film is formed on the side walls of the substrate-contact aperture 9. Polysilicon 14b is formed via the silicon oxide film 12 on the surface of the substrate-contact aperture 9, which is surrounded by the silicon oxide film 10, and in the vicinity of this surface. A silicon oxide film 18 serving as an inter-layer insulating film is formed on the polysilicon 14b. In the substrate-contact aperture region R3, a prepared hole (base hole) 22 is formed inside the region in which the substrate-contact aperture 9 has been formed. The prepared hole (base hole) 22 passes through the silicon oxide film 18 and the silicon oxide film 2 and has the first silicon substrate 1 (contact region 23) as its bottom. A side wall 24b composed of a material (e.g., tungsten) identical with that of the contact plug 24a is formed on the surface of the silicon oxide film 18 that has a step, and on the side walls of the prepared hole (base hole) 22. The first silicon substrate 1 of the substrate-contact aperture region R3 is electrically connected to the corresponding wiring layer 25 (aluminum, etc.), which has been formed on the silicon oxide film 18 and surface of the side wall 24b, through the prepared hole (base hole) 22 via the contact region 23 in which an impurity (e.g., boron) for contact is introduced to the first silicon substrate 1. The wiring layer 25 of the substrate-contact aperture region R3 is led out to the exterior of this region and is connected to a bump (not shown). The silicon oxide film 27 and the silicon nitride film 28 serving as cover films are built up (laminated) on the wiring layer 25 of substrate-contact aperture region R3 in the order mentioned.

The side wall 24b composed of tungsten or the like remains on the side wall in the prepared hole 22 of the substrate-contact aperture region R3. However, since the wiring layer 25 is deposited sufficiently within the prepared hole 22, a severance problem at the step portion of the prepared hole 22 does not arise and the connection is assured. Further, a barrier metal film (not shown) such as titanium nitride (TiN) may be laid to a prescribed thickness as a layer under the wiring layer 25, and an anti-glare film (not shown) such as TiN or polycrystalline silicon may be provided as a layer above the wiring layer 25.

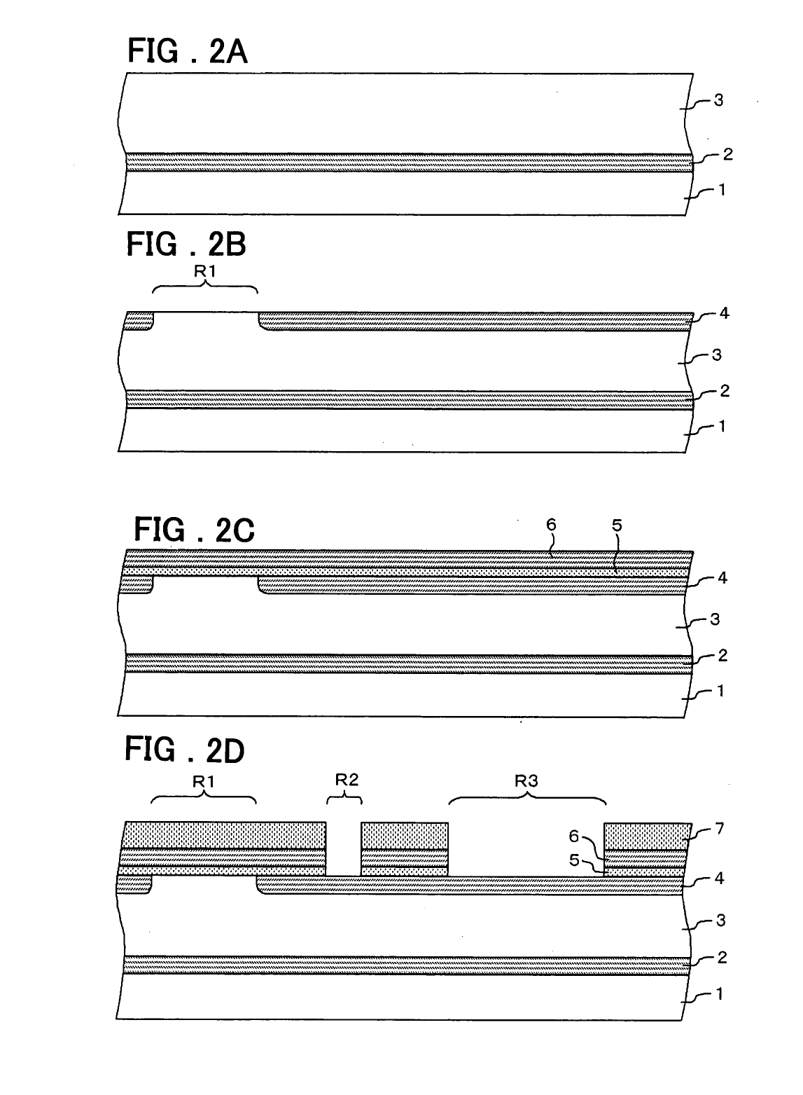

Next, a method of manufacturing the semiconductor device according to the first example of the present invention will be described. FIGS. 2A to 6C are step-by-step sectional views schematically illustrating the method of manufacturing the semiconductor device according to the first example.

The first step is to prepare a SOI-based substrate obtained by superimposing a silicon oxide film 2, which is an insulting film, and a second silicon substrate 3 on the first silicon substrate 1 (step A1; FIG. 2A).

Next, a silicon oxide film 4, which serves as a field insulating film, is formed on the SOI-based substrate, with the exception of the element-forming region R1, utilizing selective oxidation (step A2; FIG. 2B).

Next, a silicon nitride film 5 and a silicon oxide film 6, which serves as a hard mask for isolation-trench formation, are built up in the order mentioned by a chemical vapor-phase deposition method (referred to as the “CVD method” below) (step A3; FIG. 2C).

This is followed by applying a resist 7 to the entire surface of the substrate, exposing and developing the resist using a prescribed reticle, forming the pattern portions of the isolation trench region R2, which is for isolating the element-forming region R1, and of the substrate-contact aperture region R3, selectively removing the silicon nitride film 5 and silicon oxide film 6, which are exposed from the pattern portions, using an etching technique, and exposing the surface of the second silicon substrate 3 (step A4; FIG. 2D). The resist 7 is then removed.

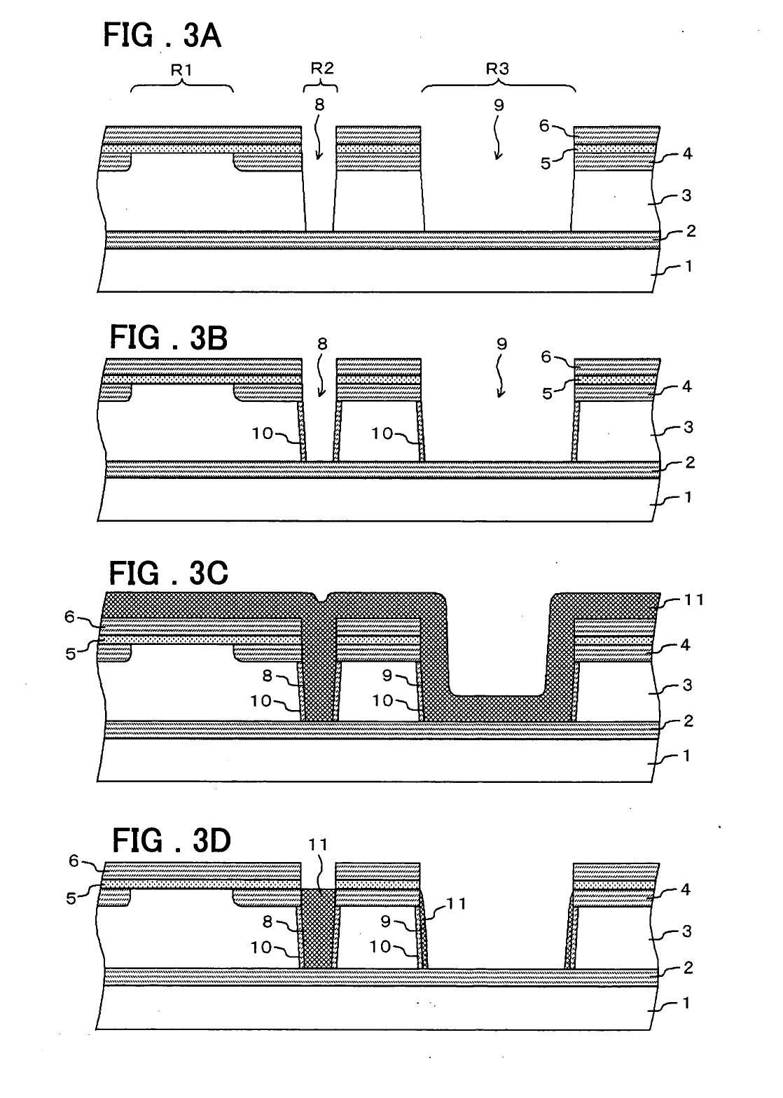

Next, by using the silicon oxide film 6 as a mask, the second silicon substrate 3 is selectively removed by an etching technique until the silicon oxide film 2 is exposed, and the isolation trench 8 and substrate-contact aperture 9 are formed (step A5; FIG. 3A). It should be noted that the substrate-contact aperture 9 is formed to have a large opening area so that it will not be filled up with polysilicon (11 in FIG. 3C) at a later step.

Next, the silicon oxide film 10 is formed on the side wall of the isolation trench 8 by a thermal treatment or by the CVD method (step A6; FIG. 3B). At this time the silicon oxide film 10 is formed on the side wall of the substrate-contact aperture 9 as well. Since isolation breakdown voltage is dependent upon the thickness of the silicon oxide film 10, the width of the isolation trench 8 and the thickness of the silicon oxide film 10 are set so as to assure the necessary isolation breakdown voltage.

Next, polysilicon 11 is deposited on the entire surface of the substrate as by the CVD method (step A7; FIG. 3C). Here the polysilicon 11 is formed as a film because it has an excellent coating property and readily buries the interior of the isolation trench 8. In order to achieve burying reliably, the polysilicon 11 is made to have a film thickness that is more than half the width of the opening of isolation trench 8.

Next, the polysilicon 11 is removed by etching-back except for the portion in the isolation trench 8 (step A8; FIG. 3D). The silicon oxide film 2 of the substrate-contact aperture region R3 is exposed at this time. It should be noted that although side-wall-shaped polysilicon 11 may remain on the side walls of the substrate-contact aperture 9, no particular problem arises. The entirety of the polysilicon 11 in the substrate-contact aperture 9 may just as well be removed.

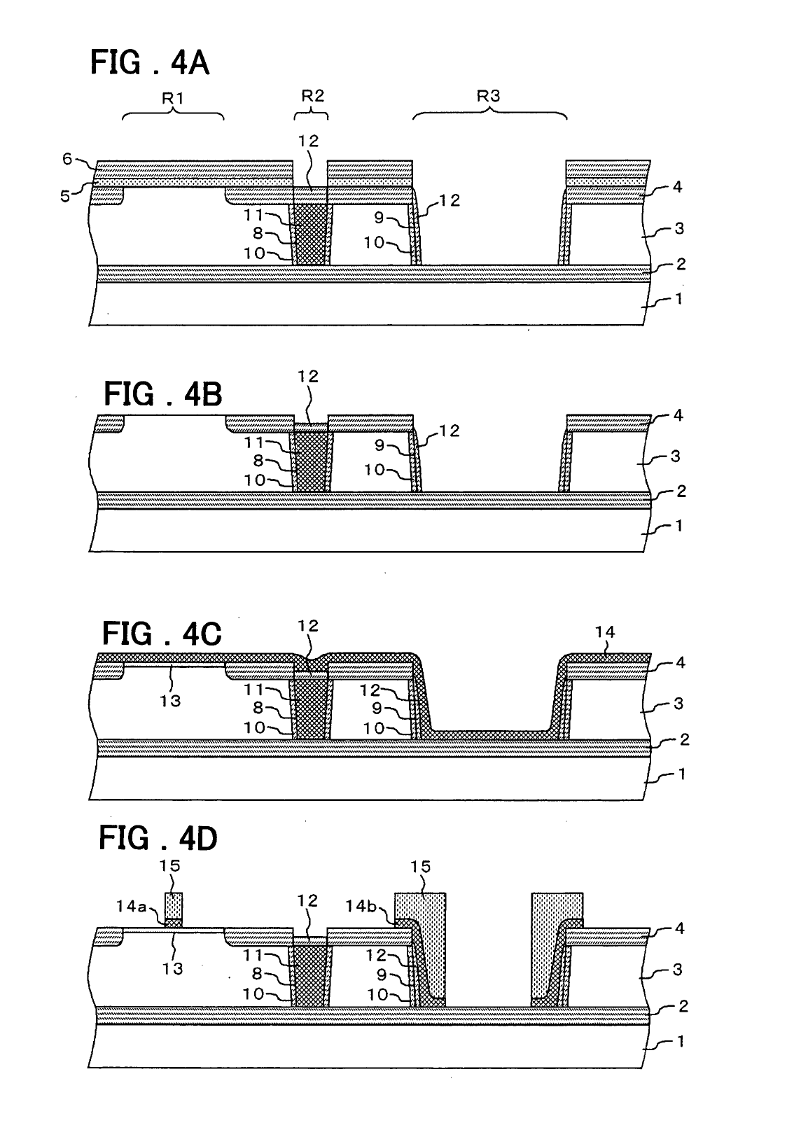

Next, the silicon oxide film 12 is formed on the surface of the polysilicon 11 by a thermal treatment (step A9; FIG. 4A). At this time the polysilicon (11 in FIG. 3D) in the substrate-contact aperture 9 is entirely or partially oxidized (entirely in FIG. 4A) and becomes the silicon oxide film 12.

Next, the silicon nitride film 5 and the silicon oxide film 6 are selectively removed (step A10; FIG. 4B). The silicon oxide film 12 also is partially or entirely removed (partially in FIG. 4B) at this time.

Next, the silicon oxide film 13 serving as a gate insulating film is formed on the exposed second silicon substrate 3 by a heat treatment, then a film of polysilicon 14 for a gate electrode is formed as by the CVD method (step A11; FIG. 4C).

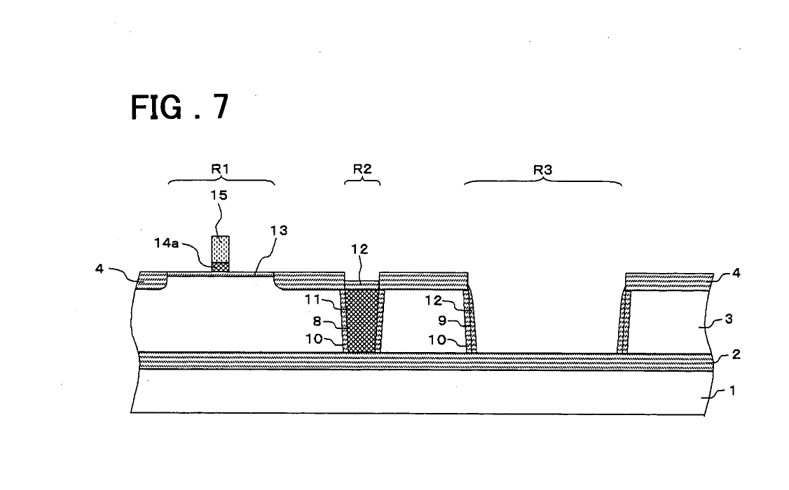

This is followed by applying a resist 15 to the entire surface of the substrate, exposing and developing the resist using a prescribed reticle, forming the gate electrode 14a and the pattern portion of polysilicon 14b of the substrate-contact aperture region R3, and selectively removing the polysilicon (14 in FIG. 4C), which is exposed from the pattern portion, using an etching technique (step A12; FIG. 4D). The silicon oxide film 2 of the substrate-contact aperture region R3 is exposed at the bottom of an etched aperture at this time. Further, the polysilicon 14b may be removed without forming a pattern (see FIG. 7). The resist 15 is then removed.

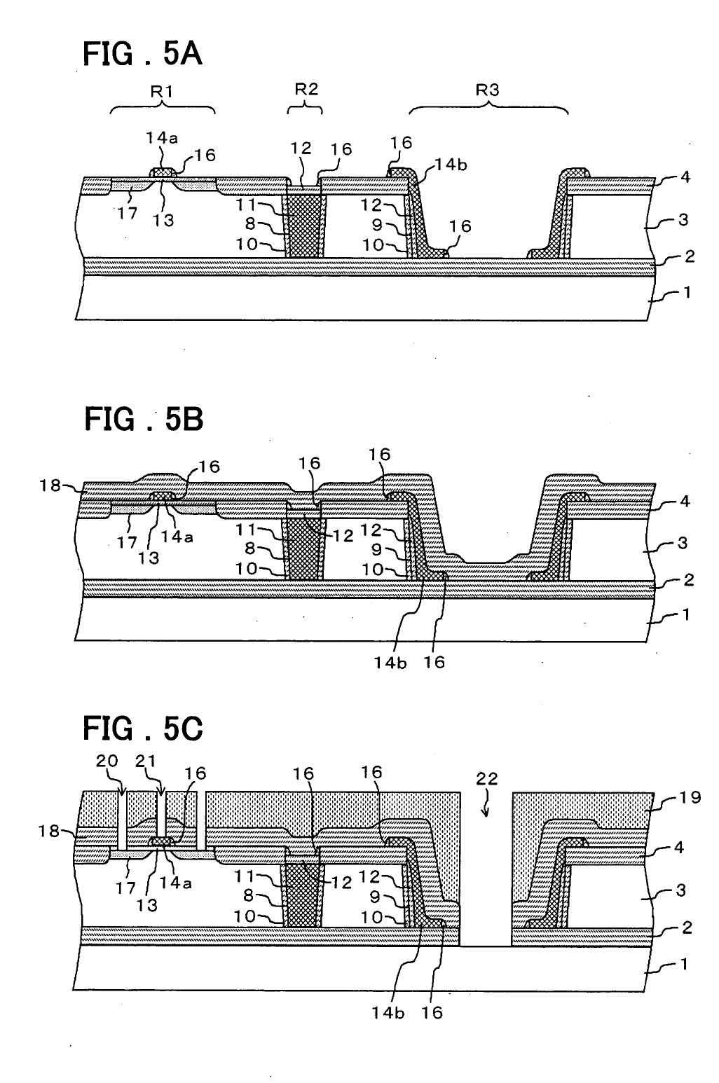

Next, by forming a silicon oxide film 16 and performing etching-back as by the CVD method, the silicon oxide film 16 that will serve as a side wall is formed on both side walls of the gate electrode 14a, after which the impurity diffusion region 17 that will serve as a source/drain region is formed (step A13; FIG. 5A). There are instances where the side-wall-shaped silicon oxide film 16 is formed also on the step-shaped portion on the substrate surface as well.

Next, the silicon oxide film 18 serving as an inter-layer insulating film is formed as by the CVD method (step A14; FIG. 5B).

This is followed by applying a resist 19 to the entire surface of the substrate, exposing and developing the resist using a prescribed reticle, forming pattern portions of prepared holes (base holes) 20, 21 for transistor contact and of prepared hole 22 for contact with the first silicon substrate 1, subsequently selectively removing the silicon oxide film 18, silicon oxide film 2 and silicon oxide film 13, which are exposed from these patterns, using an etching technique, exposing the impurity diffusion region 17 at the prepared hole (base hole) 20, exposing the gate electrode 14a at the prepared hole (base hole) 21, and exposing the first silicon substrate 1 at the prepared hole 22 (step A15; FIG. 5C). This is followed by removing the resist 19.

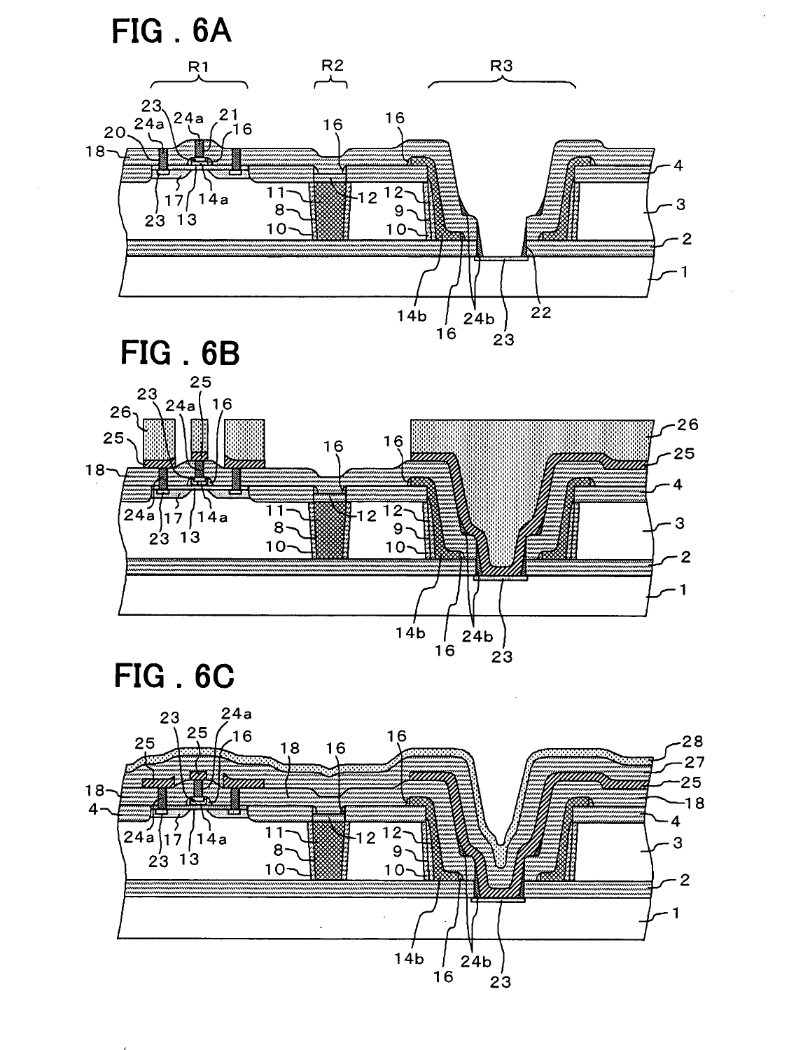

This is followed by injecting a prescribed impurity (e.g., boron) into the exposed impurity diffusion region 17, gate electrode 14a and first silicon substrate 1 through the prepared holes 20, 21, 22, subsequently forming a metal film (e.g., tungsten) for the contact plugs 24a by the CVD method, and removing unnecessary metal film by etching (etch-back) to thereby form the contact plugs 24a in the prepared holes 20, 21 (step A16; FIG. 6A). At this time the side walls 24b, which are formed of the same material as that of the contact plugs 24a, remain on the surface of the silicon oxide film 18 constituting the step portion in the substrate-contact aperture region R3, and on the side wall surfaces of the prepared hole 22.

This is followed by forming the wiring layer 25 (e.g., aluminum) on the entire substrate surface, subsequently applying a resist 26 to the entire substrate surface, exposing and developing the resist using a prescribed reticle, forming a prescribed pattern portion in the element-forming region R1, forming a pattern portion in such a manner that the wiring layer 25 will remain in the substrate-contact aperture region R3, removing the wiring layer 25 exposed from these pattern portions using an etching technique, and exposing the silicon oxide film 18 (step A17; FIG. 6B). The resist 26 is then removed.

Finally, the silicon oxide film 27 and silicon nitride film 28 serving as cover films are formed on the entire substrate surface by the CVD method in the order mentioned (step A18; FIG. 6C). As a result, a semiconductor device similar to that shown in FIG. 1 can be obtained.

In accordance with the first example, the polysilicon 11 is used as the filler of the isolation trench 8. Since the polysilicon has a burying property superior to that of the TEOS oxide film used in Patent Document 1, it is possible to form a more slender isolation trench region R2. As a result, the proportion of the surface area of the semiconductor device occupied by the isolation trench region R2 can be reduced. This leads to higher integration of semiconductor devices and makes it possible to prevent a decline in the characteristics of semiconductor devices and malfunction thereof.

Further, since the substrate-contact aperture 9 is formed at the same step as that at which the isolation trench 8 is formed, it is unnecessary to enlarge and complicate the manufacturing process.

Furthermore, a prescribed potential can be supplied to the first silicon substrate 1 from the outside. Moreover, the path from an external terminal (not shown) to the first silicon substrate 1 is formed entirely of metal film, and a prescribed impurity is introduced into the contact region 23 of the first silicon substrate 1 to thereby lower the contact resistance. As a result, the resistance of the overall path for supplying potential to the first silicon substrate 1 is lowered sufficiently and the potential of the supporting substrate can be stabilized.

### SECOND EXAMPLE

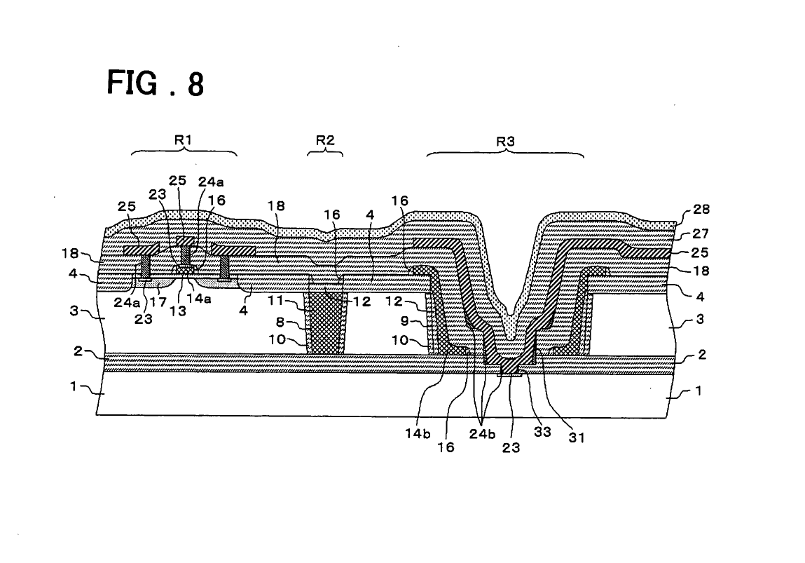

A semiconductor device according to a second example of the present invention will now be described. FIG. 8 is a partial sectional view schematically illustrating the structure of the semiconductor device according to the second example.

The semiconductor device according to the second example is an example of a case where the silicon oxide film 2 has a large film thickness. This semiconductor device differs from that of the first example in regard to prepared holes (base holes) 31, 33 of the substrate-contact aperture region R3 and the arrangement relating to these holes. The semiconductor device according to the second example is similar to that of the first example in other respects.

The substrate-contact aperture region R3 is a region in which an aperture has been formed in an appropriate vacant region on the substrate by removing the second silicon substrate 3 in order to make contact with the first silicon substrate 1. In the substrate-contact aperture region R3, the substrate-contact aperture 9 is formed passing through the silicon oxide film 4, which serves as a field insulating film, and the second silicon substrate 3, and has the silicon oxide film 2 as its bottom. In the substrate-contact aperture region R3, the silicon oxide film 10 serving as an insulating film is formed on the side wall(s) of the substrate-contact aperture 9. Polysilicon 14b is formed via the silicon oxide film 12 on the surface of the substrate-contact aperture 9, which is surrounded by the silicon oxide film 10, and in the vicinity of this surface. A silicon oxide film 18 serving as an inter-layer insulating film is formed on the polysilicon 14b. In the substrate-contact aperture region R3, the prepared hole (base hole) 31 is formed inside the region in which the substrate-contact aperture 9 has been formed. The prepared hole 31 has a bottom extending from the silicon oxide film 18, which has been formed in the substrate-contact aperture 9, to the silicon oxide film 2 (In FIG. 8, the bottom is the silicon oxide film 2). Formed in the region in which the prepared hole 31 has been formed and passing through the silicon oxide film 18 and silicon oxide film 2 is the prepared hole 33. The side wall 24b formed of a material (e.g., tungsten) identical with that of the contact plug 24a is formed on the surface of the silicon oxide film 18 having the step, and on the side walls of the prepared holes 31 and 33. The first silicon substrate 1 of the substrate-contact aperture region R3 is electrically connected to the corresponding wiring layer 25 (aluminum, etc.), which has been formed on the silicon oxide films 18, 2 and surface of the side wall 24b, through the prepared holes 31, 33 via the contact region 23 in which an impurity (e.g., boron) for contact is introduced to the first silicon substrate 1. The wiring layer 25 of the substrate-contact aperture region R3 is led out to the exterior of this region and is connected to a bump (not shown). The silicon oxide film 27 and the silicon nitride film 28 serving as cover films are built up on the wiring layer 25 of substrate-contact aperture region R3 in the order mentioned.

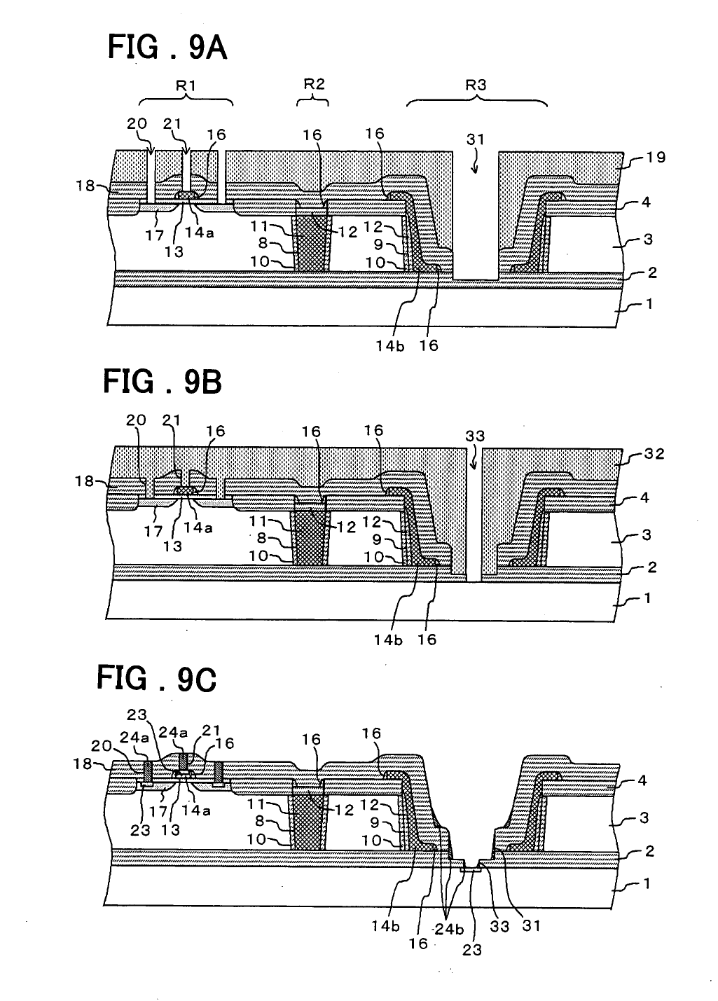

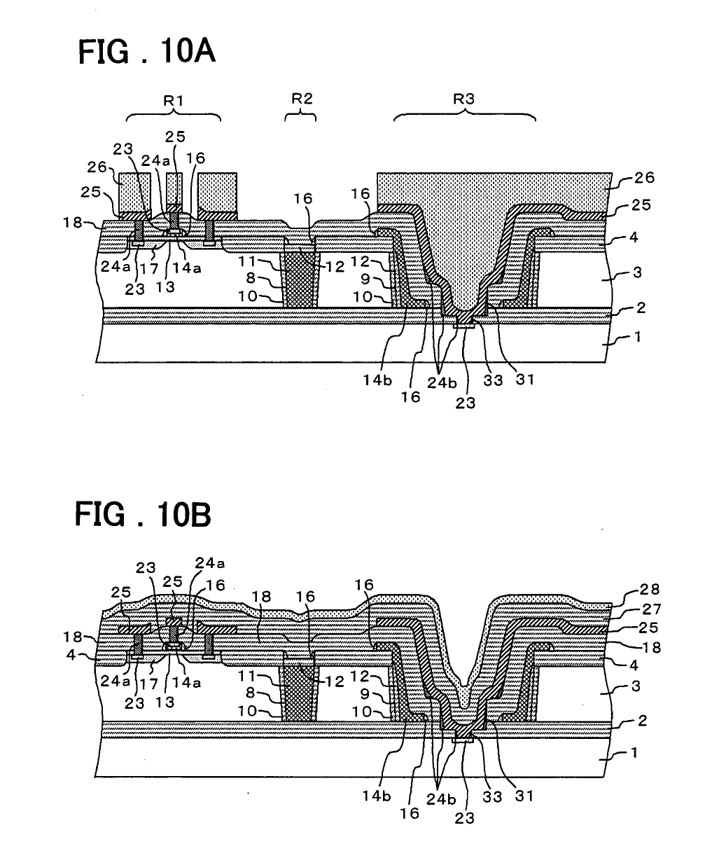

Next, a method of manufacturing the semiconductor device according to the second example of the present invention will be described. FIGS. 9A to 10B are step-by-step sectional views schematically illustrating a method of manufacturing the semiconductor device according to the second example.

First, the substrate (see FIG. 5B) obtained up to formation of the silicon oxide film 18 serving as the inter-layer insulating film is manufactured by a method of manufacture similar to that of steps A1 to A14 in the first example (step B1).

This is followed by applying a resist 19 to the entire surface of the substrate, exposing and developing the resist using a prescribed reticle, forming the pattern portion of the prepared hole 31 for contact with the first silicon substrate 1, subsequently selectively removing the films from silicon oxide film 18 to silicon oxide film 2, which are exposed from the pattern portion, using an etching technique, exposing the impurity diffusion region 17 at the prepared hole 20, exposing the gate electrode 14a at the prepared hole 21, and removing films from the silicon oxide film 18 to the silicon oxide film 2 at the prepared hole 31 in such a manner that the prepared hole 31 will have a bottom extending from the silicon oxide film 18 to the silicon oxide film 2 (step B2; FIG. 9A). The resist 19 is then removed.

This is followed by applying a resist 32 to the entire substrate surface, exposing and developing the resist using a prescribed reticle, forming the pattern portion of the prepared hole 33 for contact with the first silicon substrate 1, selectively removing the silicon oxide film 2 (inclusive of the first silicon substrate 18 if this film remains), which is exposed from this pattern portion, using an etching technique, and exposing the first silicon substrate 1 (step B3; FIG. 9B). The resist 32 is then removed.

This is followed by injecting a prescribed impurity (e.g., boron) into the exposed impurity diffusion region 17, gate electrode 14a and first silicon substrate 1 through the prepared holes 20, 21, 33, subsequently forming a metal film (e.g., tungsten) for the contact plugs 24a by the CVD method, and removing unnecessary metal film by etching (etch-back) to thereby form the contact plugs 24a in the prepared holes 20, 21 (step B4; FIG. 9C). At this time the side walls 24b, which are formed of the same material as that of the contact plugs 24a, remain on the surfaces of the silicon oxide films 18, 2 of the substrate-contact aperture region R3, and on the side wall surfaces of the prepared holes 31, 33.

This is followed by forming the wiring layer 25 (e.g., aluminum) on the entire substrate surface, subsequently applying a resist 26 to the entire substrate surface, exposing and developing the resist using a prescribed reticle, forming a prescribed pattern portion in the element-forming region R1, forming a pattern portion in such a manner that the wiring layer 25 will remain in the substrate-contact aperture region R3, removing the wiring layer 25 exposed from these pattern portions using an etching technique, and exposing the silicon oxide film 18 (step A17; FIG. 6B). The resist 26 is then removed.

Finally, the silicon oxide film 27 and silicon nitride film 28 serving as cover films are formed on the entire substrate surface by the CVD method in the order mentioned (step B6; FIG. 10B). As a result, a semiconductor device similar to that shown in FIG. 2 can be obtained.

In accordance with the second example, effects similar to those of the first example are obtained. In addition, although the number of manufacturing steps is greater in comparison with the first example, contacts with the first silicon substrate 1 can be formed even in a case where the buried oxide film (the silicon oxide film 2) of an SOI-based substrate has a large film thickness.

Other features and advantages of the present invention will be apparent from the following description taken in conjunction with the accompanying drawings, in which like reference characters designate the same or similar parts throughout the figures thereof.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a substrate obtained by building up on a first semiconductor substrate a second semiconductor substrate via a first insulating film;
an element-forming region in which an element has been formed on the second semiconductor substrate;
a substrate contact aperture region in which an aperture has been formed by removing the second semiconductor substrate;
an isolation trench region in which an isolation trench has been formed for isolating the element on the second semiconductor substrate;
a second insulating film that has been formed on the surface of the isolation trench;
polysilicon filling the isolation trench;
a prepared hole penetrating the first insulating film of said substrate contact aperture region and leading to the first semiconductor substrate; and
a wiring layer connected to the first semiconductor substrate within said prepared hole.

2. The device according to claim 1, wherein said prepared hole penetrates also a third insulating film that has been formed on the first insulating film of said substrate contact aperture region.

3. The device according to claim 1, wherein said prepared hole has a step.

4. A method of manufacturing a semiconductor device, comprising:
forming a field insulating film in a region other than an element-forming region on a substrate obtained by building up on a first semiconductor substrate a second semiconductor substrate via a first insulating film;
forming on the field insulating film a hard mask having a pattern portion for forming an isolation trench and a substrate contact aperture;
removing the field insulating film and the second semiconductor substrate that are exposed from the pattern portion of the hark mask, thereby exposing the first insulating film, and forming the isolation trench and the substrate contact aperture;
forming a second insulating film on the surface of at least the second semiconductor substrate in the isolation trench and substrate contact aperture;
depositing polysilicon to a prescribed thickness so as to completely fill at least the isolation trench;
etching back the polysilicon by a prescribed amount;
forming an insulating film on the surface of the polysilicon followed by removing the hard mask;
forming a prepared hole that leads to the first semiconductor substrate by removing at least the first insulating film within the substrate contact aperture; and
forming a wiring layer on the first semiconductor substrate within the prepared hole.

5. The method according to claim 4, further comprising the following steps between said removing the hard mask and said forming the prepared hole:
forming a desired element in the element-forming region; and
forming an inter-layer insulating film on the entire surface of the substrate;
wherein said forming the prepared hole includes forming a prepared hole that leads to the first semiconductor substrate by removing the inter-layer insulating film and the first insulating film within the substrate contact aperture and, at the same time, forming a prepared hole that leads to the element by removing the inter-layer insulating film in the element-forming region.

6. The method according to claim 5, further comprising: forming a contact plug at least in the prepared hole that leads to the element, this step being inserted between said forming the prepared hole and forming the wiring layer;
wherein said step of forming the wiring layer includes forming the wiring layer on the contact plug as well.

7. The method according to claim 5, wherein said forming the prepared hole includes:
forming a first prepared hole by removing films from the inter-layer insulating film to the first insulating film within the substrate contact aperture in such a manner that the first prepared hole has a bottom extending from the inter-layer insulating film to the first insulating film; and
subsequently forming a second prepared hole having a width smaller than that of the first prepared hole by removing films from the inter-layer insulating film to the first insulating film within the first prepared hole in such a manner that the second prepared hole leads to the first semiconductor substrate.
